(19) United States
(12) Patent Application Publication
(10) Pub. No.: US 2022/0102074 A1
(43) Pub. Date: Mar. 31, 2022

(54) ELECTRONIC COMPONENT AND BOARD HAVING THE SAME

(71) Applicant: SAMSUNG ELECTRO-MECHANICS CO., LTD., Suwon-si (KR)

(72) Inventors: Mi Na Hyun, Suwon-si (KR); Beom Joon Cho, Suwon-si (KR); Ki Young Kim, Suwon-si (KR)

(21) Appl. No.: 17/327,941

(22) Filed: May 24, 2021

(30) Foreign Application Priority Data
Sep. 29, 2020 (KR) 10-2020-0127327

(51) Int. Cl. H01G 4/232; H05K 1/18

(52) U.S. Cl. CPC H01G 4/2325; H01G 4/1227; H05K 1/181

(57) ABSTRACT

An electronic component includes: a capacitor body; a pair of external electrodes disposed on opposite end surfaces of the capacitor body, respectively; and a pair of metal frames connected to the pair of external electrodes, respectively. A coefficient of thermal expansion of the pair of metal frames has a value between a coefficient of thermal expansion of the capacitor body and a coefficient of thermal expansion of a solder.

### CROSS-REFERENCE TO RELATED APPLICATION(S)

This application claims the benefit of priority to Korean Patent Application No. 10-2020-0127327, filed on Sep. 29, 2020 in the Korean Intellectual Property Office, the disclosure of which is incorporated herein by reference in its entirety.

### TECHNICAL FIELD

The present disclosure relates to an electronic component and a board having the same.

### BACKGROUND

A multilayer capacitor has been used as several electronic apparatuses since it has a small size may implement high capacitance.

Recently, in accordance with the rapid rise to prominence of eco-friendly vehicles and electric vehicles, the importance of a power driving system inside such vehicles has increased. Therefore, a demand for a multilayer capacitor required for the power driving system has also increased.

A multilayer capacitor has been required to have a high level of thermal reliability, electrical reliability, and mechanical reliability in order to be used as a component of a vehicle.

In particular, in accordance with an increase in a density of components mounted inside the vehicle, a multilayer capacitor which is easily installed in a limited space, may implement high capacitance, and has excellent durability against vibration and deformation has been required.

In addition, as a method of improving durability of the multilayer capacitor against vibrations and deformation, there is a method of mounting the multilayer capacitor so as to be spaced apart from a circuit board using a metal frame.

However, in a case of an electronic component using such a metal frame, the metal frame is in contact with both of the multilayer capacitor and the circuit board, and deterioration may thus occur at an interface between the metal frame and the multilayer capacitor and the circuit board due to a difference in coefficients of thermal expansion between respective materials under changing environmental conditions such as a temperature cycle.

Therefore, a crack may occur in a solder for bonding the metal frame to an electrode pad of the circuit board, such that a defective rate of the electronic component after an environment test may increase.

### SUMMARY

An electronic component and a board having the same according to an aspect of the present disclosure may improve durability of a multilayer capacitor against vibrations and deformation, increase bonding force of a metal frame to a circuit board, and prevent a solder crack for attaching the metal frame to the circuit board after an environment test.

According to an aspect of the present disclosure, an electronic component may include: a capacitor body; a pair of external electrodes disposed on opposite end surfaces of the capacitor body, respectively; and a pair of metal frames connected to the pair of external electrodes, respectively. A coefficient of thermal expansion of the pair of metal frames has a value between a coefficient of thermal expansion of the capacitor body and a coefficient of thermal expansion of a solder.

The coefficient of thermal expansion of the pair of metal frames may be 18.4 ppm/° C. or more.

The coefficient of thermal expansion of the pair of metal frames may be 18.4 to 26.2 ppm/° C.

The capacitor body may include dielectric layers and a plurality of internal electrodes alternately disposed with each of the dielectric layers interposed therebetween.

Each of the pair of external electrodes may include: a head portion disposed on one surface among the opposite end surfaces of the capacitor body; and a band portion extending from the respective head portion onto portions of upper and lower surfaces and opposite side surfaces of the capacitor body that are connected to the opposite end surfaces of the capacitor body.

Each of the metal frames may include: a connection portion connected to the respective head portion; and a mounting portion bent at and extending from a lower end of the respective connection portion.

The mounting portion of a first metal frame among the pair of metal frames may extend toward the mounting portion of a second metal frame among the pair of metal frames positioned on an opposite side to the mounting portion of the first metal frame.

Each connection portion may have at least one through-hole formed therein.

According to another aspect of the present disclosure, a board having an electronic component may include: a circuit board having a plurality of electrode pads disposed on an upper surface thereof; an electronic component mounted on the circuit board and including a pair of metal frames connected to the plurality of electrode pads, respectively; and solders connecting the plurality of electrode pads to the pair of metal frames, respectively. The electronic component further includes: a capacitor body; and a pair of external electrodes disposed on opposite end surfaces of the capacitor body, respectively, and connected to the pair of metal frames, respectively. A coefficient of thermal expansion of the pair of metal frames may have a value between a coefficient of thermal expansion of the capacitor body and a coefficient of thermal expansion of the solders.

A portion of each solder may pass through the at least one through-hole of the respectively connection portion and extend onto an upper surface of the respective mounting portion.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic perspective view illustrating a multilayer capacitor according to an exemplary embodiment in the present disclosure;

FIGS. 2A and 2B are plan views illustrating, respectively, first and second internal electrodes used in FIG. 1;

FIG. 3 is a cross-sectional view taken along line I-I′ of FIG. 1;

FIG. 4 is a schematic perspective view illustrating a coupling structure between an electronic component and a circuit board according to an exemplary embodiment in the present disclosure;

FIG. 5 is a cross-sectional view taken along line II-II′ of FIG. 4;

FIG. 6 is a graph illustrating a crack occurrence rate of a solder for bonding a metal frame to a circuit board depending on a coefficient of thermal expansion of the metal frame; and

FIG. 7 is a perspective view illustrating metal frames separated from a multilayer capacitor according to another exemplary embodiment in the present disclosure.

### DETAILED DESCRIPTION

Hereinafter, exemplary embodiments of the present disclosure will now be described in detail with reference to the accompanying drawings.

Directions will be defined in order to clearly describe exemplary embodiments in the present disclosure. X, Y and Z in the drawings refer to a length direction, a width direction, and a thickness direction of a multilayer capacitor and an electronic component, respectively.

Here, the Z direction may be used as the same concept as a stacked direction in which dielectric layers are stacked in the present exemplary embodiment.

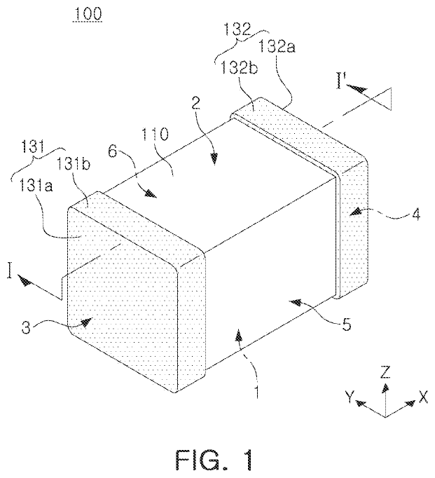

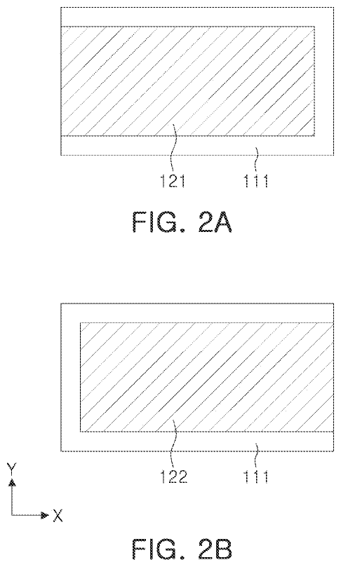

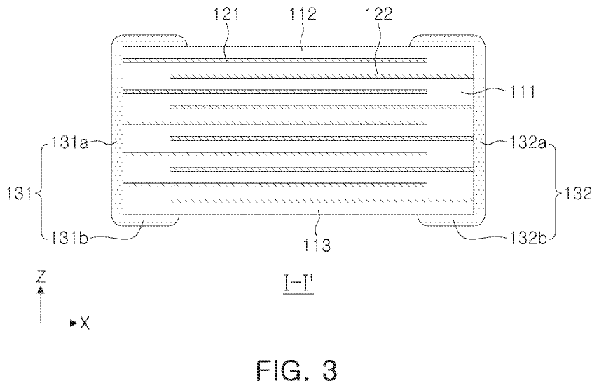

FIG. 1 is a schematic perspective view illustrating a multilayer capacitor according to an exemplary embodiment in the present disclosure, FIGS. 2A and 2B are plan views illustrating, respectively, first and second internal electrodes used in FIG. 1, and FIG. 3 is a cross-sectional view taken along line I-I′ of FIG. 1.

A structure of a multilayer capacitor 100 used in an electronic component according to the present exemplary embodiment will be described with reference to FIGS. 1 through 3.

The multilayer capacitor 100 according to the present exemplary embodiment may include a capacitor body 110 and first and second external electrodes 131 and 132 on opposite end surfaces of the capacitor body 110 in the X direction, respectively.

The capacitor body 110 may be formed by stacking a plurality of dielectric layers 111 in the Z direction and then sintering the plurality of dielectric layers 111.

Adjacent dielectric layers 111 of the capacitor body 110 may be integrated with each other so that boundaries therebetween are not readily apparent without using a scanning electron microscope (SEM).

In addition, the capacitor body 110 may include a plurality of dielectric layers 111 and first and second internal electrodes 121 and 122 alternately disposed in the Z direction with each of the dielectric layers 111 interposed therebetween. In this case, the first and second internal electrodes 121 and 122 may have different polarities.

In addition, the capacitor body 110 may include an active region and cover regions 112 and 113.

The active region may contribute to forming capacitance of the multilayer capacitor 100.

In addition, the cover regions 112 and 113 may be provided as margin portions on upper and lower surfaces of the active region in the Z direction, respectively.

The cover regions 112 and 113 may be formed by stacking a single dielectric layer or two or more dielectric layers on the upper and lower surfaces of the active region, respectively.

In addition, the cover regions 112 and 113 may basically serve to prevent the first and second internal electrodes 121 and 122 from being damaged due to physical or chemical stress.

A shape of the capacitor body 110 is not particularly limited, but may be substantially a hexahedral shape.

In the present exemplary embodiment, the capacitor body 110 may include first and second surfaces 1 and 2 opposing each other in the Z direction, third and fourth surfaces 3 and 4 connected to the first and second surfaces 1 and 2 and opposing each other in the X direction, and fifth and sixth surfaces 5 and 6 connected to the first and second surfaces 1 and 2, connected to the third and fourth surfaces 3 and 4, and opposing each other. Here, the first surface 1 may be amounted surface.

In addition, a shape and a dimension of the capacitor body 110 and the number of stacked dielectric layers 111 are not limited to those illustrated in the drawings of the present exemplary embodiment.

The dielectric layer 111 may include ceramic powders such as BaTiO₃-based ceramic powders or the like.

An example of the BaTiO₃-based ceramic powder may include (Ba₁₋ₓCaₓ)TiO₃, Ba(Ti_{1-y}Ca_{y})O₃, (Ba₁₋ₓCaₓ)(Ti_{1-y}Zr_{y})O₃, Ba(Ti_{1-y}Zr_{y})O₃, or the like, in which Ca, Zr or the like, is partially solid-dissolved in BaTiO₃. However, the BaTiO₃-based ceramic powder according to the present disclosure is not limited thereto.

In addition, the dielectric layer 111 may further include a ceramic additive, an organic solvent, a plasticizer, a binder, a dispersant, and the like.

The ceramic additives may contain a transition metal oxide or a transition metal carbide, rare earth elements, magnesium (Mg), aluminum (Al), or the like.

The first and second internal electrodes 121 and 122 may be electrodes to which different polarities are applied.

The first and second internal electrodes 121 and 122 may be formed on the dielectric layers 111 and stacked in the Z direction, respectively.

In addition, the first and second internal electrodes 121 and 122 may be alternately disposed in the capacitor body 110 to face each other along the Z direction with each of the dielectric layers 111 interposed therebetween.

In this case, the first and second internal electrodes 121 and 122 may be electrically insulated from each other by each of the dielectric layers 111 disposed therebetween.

Meanwhile, a structure in which the plurality of internal electrodes are stacked in the Z direction has been illustrated and described in the present exemplary embodiment. However, the present disclosure is not limited thereto, and may also be applied to a structure in which the internal electrode are stacked in the Y direction, if necessary.

One end portion of the first internal electrode 121 may be exposed through the third surface 3 of the capacitor body 110.

The one end portion of the first internal electrode 121 exposed through the third surface 3 of the capacitor body 110 as described above may be electrically connected to the first external electrode 131 disposed on one end surface of the capacitor body 110 in the X direction.

One end portion of the second internal electrode 122 may be exposed through the fourth surface 4 of the capacitor body 110.

The one end portion of the second internal electrode 122 exposed through the fourth surface 4 of the capacitor body 110 as described above may be electrically connected to the second external electrode 132 disposed on the other end surface of the capacitor body 110 in the X direction.

According to the configuration as described above, when predetermined voltages are applied to the first and second external electrodes 131 and 132, electric charges may be accumulated between the first and second internal electrodes 121 and 122.

In this case, capacitance of the multilayer capacitor 100 may be in proportion to an area of the first and second internal electrodes 121 and 122 overlapping each other along the Z direction in the active region.

In addition, a material of each of the first and second internal electrodes 121 and 122 is not particularly limited.

In addition, the first and second internal electrodes 121 and 122 may be formed using a conductive paste formed of one or more of a noble metal material, nickel (Ni), and copper (Cu).

The noble metal material may be platinum (Pt), palladium (Pd), a palladium-silver (Pd—Ag) alloy, and the like.

In addition, a method of printing the conductive paste may be a screen-printing method, a gravure printing method, or the like, but is not limited thereto.

Voltages having different polarities may be provided to the first and second external electrodes 131 and 132, respectively, and the first and second external electrodes 131 and 132 may be disposed on the opposite end surfaces of the capacitor body 110 in the X direction, respectively, and may be electrically connected to the exposed end portions of the first and second internal electrodes 121 and 122, respectively.

The first external electrode 131 may include a first head portion 131a and a first band portion 131b.

The first head portion 131a may be disposed on the third surface 3 of the capacitor body 110.

The first head portion 131a may be in contact with the end portions of the first internal electrodes 121 externally exposed through the third surface 3 of the capacitor body 110 to serve to electrically connect the first internal electrodes 121 and the first external electrode 131 to each other.

The first band portion 131b may extend from the first head portion 131a to parts of the first, second, fifth, and sixth surfaces 1, 2, 5, and 6 of the capacitor body 110.

The first band portion 131b may serve to improve fixing strength of the first external electrode 131.

The second external electrode 132 may include a second head portion 132a and a second band portion 132b.

The second head portion 132a may be disposed on the fourth surface 4 of the capacitor body 110.

The second head portion 132a may be in contact with the end portions of the second internal electrodes 122 externally exposed through the fourth surface 4 of the capacitor body 110 to serve to electrically connect the second internal electrodes 122 and the second external electrode 132 to each other.

The second band portion 132b may extend from the second head portion 132a to parts of the first, second, fifth, and sixth surfaces 2, 2, 5, and 6 of the capacitor body 110.

The second band portion 132b may serve to improve fixing strength of the second external electrode 132.

Meanwhile, the first and second external electrodes 131 and 132 may further include plating layers.

The plating layers may include first and second nickel (Ni) plating layers disposed on the capacitor body 110 and first and second tin (Sn) plating layers covering, respectively, the first and second nickel plating layers.

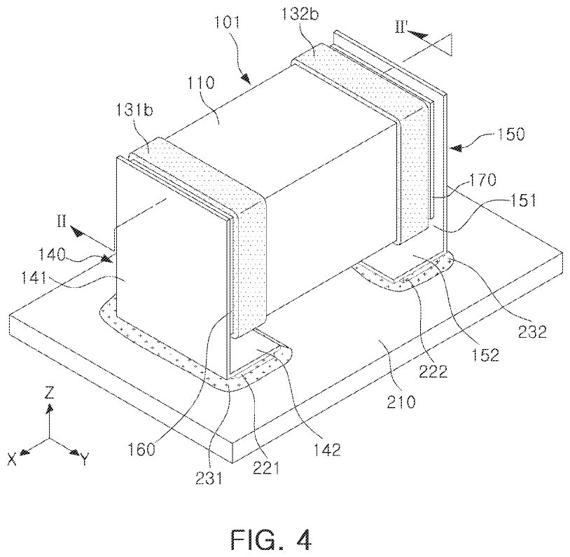

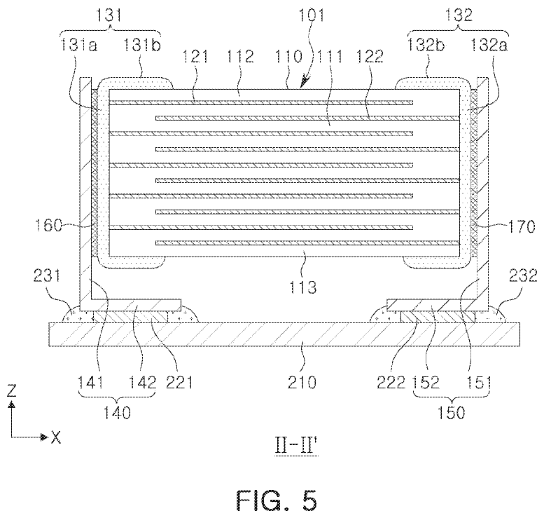

FIG. 4 is a schematic perspective view illustrating a coupling structure between an electronic component and a circuit board according to an exemplary embodiment in the present disclosure, and FIG. 5 is a cross-sectional view taken along line II-II′ of FIG. 4.

Referring to FIGS. 4 and 5, an electronic component 101 according to the present exemplary embodiment may include a multilayer capacitor 100 including a capacitor body 110 and first and second external electrodes 131 and 132 and first and second metal frames 140 and 150 connected to the first and second external electrodes 131 and 132, respectively.

The first metal frame 140 may include a first connection portion 141 and a first mounting portion 142.

The first connection portion 141 may be bonded and physically connected to the first head portion 131a of the first external electrode 131, and may be electrically connected to the first head portion 131a of the first external electrode 131.

In this case, a first conductive bonding layer 160 may be disposed between the first head portion 131a of the first external electrode 131 and the first connection portion 141.

The first conductive bonding layer 160 may be formed of a high-temperature solder, a conductive bonding material or the like, and is not limited thereto.

The first mounting portion 142 may be bent at and extend from a lower end of the first connection portion 141 toward a second mounting portion 152 of the second metal frame 150 positioned on an opposite side to the first mounting portion 142 in the X direction, and be formed horizontal to the mounted surface.

The first mounting portion 142 may serve as a connection terminal at the time of mounting the electronic component 101 on a circuit board 210.

In this case, the first mounting portion 142 may be disposed to be spaced apart from a lower end of the multilayer capacitor 100.

A coefficient of thermal expansion of the first metal frame 140 may have a value between a coefficient of thermal expansion of the capacitor body 110 and a coefficient of thermal expansion of a solder to be described later.

In this case, the coefficient of thermal expansion of the first metal frame 140 may be 18.4 ppm/° C. or more, and preferably, 18.4 to 26.2 ppm/° C.

The second metal frame 150 may include a second connection portion 151 and the second mounting portion 152.

The second connection portion 151 may be physically connected to the second head portion 132a of the second external electrode 132, and may be electrically connected to the second head portion 132a of the second external electrode 132.

In this case, a second conductive bonding layer 170 may be disposed between the second head portion 132a of the second external electrode 132 and the second connection portion 151.

The second conductive bonding layer 170 may be formed of a high-temperature solder, a conductive bonding material or the like, and is not limited thereto.

The second mounting portion 152 may be bent at and extend from a lower end of the second connection portion 151 toward the first mounting portion 122 of the first metal frame 140 positioned on an opposite side to the second mounting portion 152 in the X direction, and be formed horizontal to the mounted surface.

The second mounting portion 152 may serve as a connection terminal at the time of mounting the electronic component 101 on the circuit board 210.

In this case, the second mounting portion 152 may be disposed to be spaced apart from a lower end of the multilayer capacitor 100.

A coefficient of thermal expansion of the second metal frame 150 may have a value between a coefficient of thermal expansion of the capacitor body 110 and a coefficient of thermal expansion of a solder to be described later.

In this case, the coefficient of thermal expansion of the second metal frame 150 may be 18.4 ppm/° C. or more, and preferably, 18.4 to 26.2 ppm/° C.

A board according to the present exemplary embodiment may include a circuit board 210 and first and second electrode pads 221 and 222 disposed on an upper surface of the circuit board 210 so as to be spaced apart from each other in the X direction.

In this case, the electronic component 101 may be mounted on the circuit board 210 in a state in which the first and second mounting portions 142 and 152 of the first and second metal frames 140 and 150 positioned on the first and second electrode pads 221 and 222, respectively, so as to be in contact with the first and second electrode pads 221 and 222, respectively.

The first mounting portion 142 may be bonded and electrically and physically connected to the first electrode pad 221 by a solder 231, and the second mounting portion 152 may be bonded and electrically and physically connected to the second electrode pad 222 by a solder 232.

A multilayer capacitor according to the related art has a structure in which external electrodes thereof and a circuit board are in direct contact with each other by solders when it is mounted on the circuit board.

Therefore, heat or mechanical deformation generated from the circuit board is directly transferred to the multilayer capacitor, and it is thus difficult to secure a high level of reliability of the multilayer capacitor.

In the electronic component according to the present exemplary embodiment, a gap between the multilayer capacitor 100 and the circuit board 210 may be secured by bonding the first and second metal frames 140 and 150 to both end portions of the multilayer capacitor 100, respectively.

Therefore, when the electronic component 101 is mounted on the circuit board 210, stress may not be directly transferred from the circuit board 210 to the multilayer capacitor 100, such that thermal reliability, electrical reliability, mechanical reliability, and the like, of the electronic component 101 may be improved.

However, in a case of an electronic component using a metal frame, the metal frame is in contact with both of a multilayer capacitor and a circuit board, and deterioration may thus occur on an interface between the metal frame and the multilayer capacitor and the circuit board due to a difference in coefficient of thermal expansion between respective materials under an changing environmental conditions such as a temperature cycle.

In particular, under the changing environmental conditions such as the temperature cycle, large thermal stress may occur on an interface between a solder and the metal frame due to a difference in coefficient of thermal expansion between the solder and the metal frame to deteriorate the interface between the solder and the metal frame and cause a crack in the solder, such that a physical or electrical defect may occur in the electronic component after an environment test.

In the present exemplary embodiment, the coefficient of thermal expansion of the metal frames 140 and 150 may have the value between the coefficient of thermal expansion of the capacitor body 110 and the coefficient of thermal expansion of the solder to cancel the thermal stress occurring on the interface between the metal frame and the solder, and a possibility that the interface will be deteriorated due to the thermal stress under the changing environmental conditions such as the temperature cycle may thus be reduced.

Therefore, bonding force between the metal frames 140 and 150 and the circuit board 210 may be secured at a predetermined level or more, the deterioration of the interface under the changing environmental conditions such as the temperature cycle may be suppressed, and the solder crack for bonding the metal frames 140 and 150 to the circuit board 210 may be prevented to reduce a defect rate of the electronic component after the environment test.

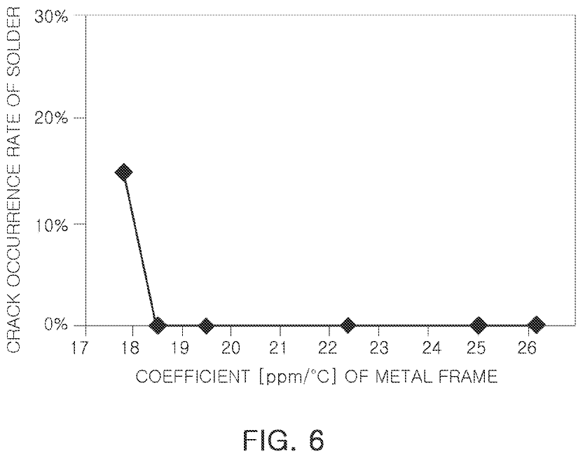

FIG. 6 is a graph illustrating a crack occurrence rate of the solder for bonding the metal frame to the circuit board depending on a coefficient of thermal expansion of the metal frame when the electronic component according to the present exemplary embodiment was mounted on the circuit board.

Here, length×width of the multilayer capacitor may be 3.2 mm×2.5 mm, a distance from the mounting portion of the metal frame to the band portion of the external electrode may be 1.0 mm±0.2 mm, length×width of the mounting portion may be 0.8 mm×2.5 mm, and length×width of the electrode pad may be 1.4 mm×2.9 mm.

In addition, the metal frame may include a material such as Al or Cu or alloys thereof, and the solder may be formed of a material including Sn, Ag, and Cu.

In order to confirm the solder crack for bonding the metal frame to the circuit board, twenty electronic components each including the multilayer capacitor and the metal frame that have the above specifications were bonded to and mounted on printed circuit boards (PCBs) by solders for each of conditions of coefficients of thermal expansion and were then subjected to a temperature cycle in a section of −55 to 200° C. including 200° C., which is a temperature at which the multilayer capacitor is actually used, 1,000 times, and it was then observed whether or not the cracks has occurred in the solder, and, and a crack occurrence rate of the solder was shown in Table 1 and FIG. 6.

TABLE 1

| | Coefficient of Thermal Expansion | | | | | |
|---|---|---|---|---|---|---|
| | (ppm/° C.) of Metal Frame | | | | | |
| | 17.8 | 18.4 | 19.4 | 22.3 | 25 | 26.2 |
| Crack Occurrence | 15 | 0 | 0 | 0 | 0 | 0 |
| Rate (%) of Solder | | | | | | |

In general, a coefficient of thermal expansion of the solder is 23.5 ppm/° C. The solder crack occurs due to thermal stress caused by a difference in a coefficient of thermal expansion between the metal frame and the solder in a harsh temperature cycle environment.

It may be confirmed from Table 1 and FIG. 6 that when the coefficient of thermal expansion of the metal frame is similar to 23.5 ppm/° C., which is the coefficient of thermal expansion of the solder, the solder crack did not occur after the temperature cycle.

In addition, when the coefficient of thermal expansion of the metal frame is less than 18.4 ppm/° C., the solder crack occurred, and when the coefficient of thermal expansion of the metal frame is 17.8 ppm/° C., the solder crack occurred at 15%.

Therefore, a preferable coefficient of thermal expansion of the metal frame according to the present disclosure may be considered as 18.4 ppm/° C. or more.

Meanwhile, the coefficient of thermal expansion of the metal frame is generally set to 25 ppm/° C. or less, but as a result of a test, the solder crack did not occur even when the coefficient of thermal expansion of the metal frame is 26.2 ppm/° C., which is higher than 25 ppm/° C.

In addition, in the present exemplary embodiment, when the coefficient of thermal expansion of the metal frame exceeds than 26.2 ppm/° C., a difference in coefficient of thermal expansion between the metal frame and the capacitor body may be excessively large, such that the deterioration of the interface between the multilayer capacitor and the metal frame may occur.

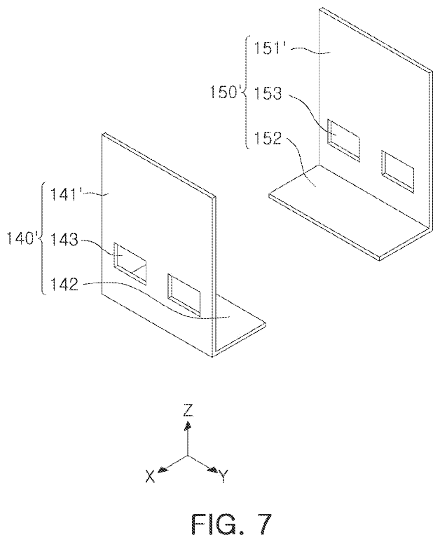

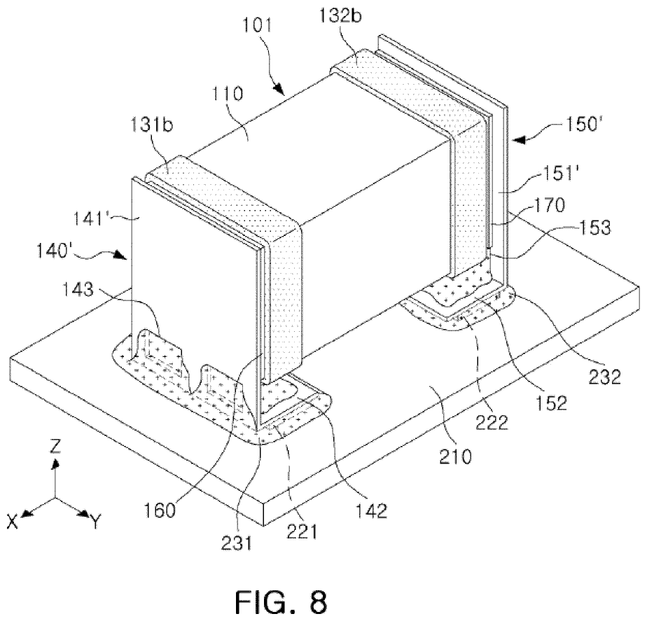

FIG. 7 is a perspective view illustrating metal frames separated from a multilayer capacitor according to another exemplary embodiment in the present disclosure.

Referring to FIG. 7, in a first metal frame 140′ according to the present exemplar embodiment, first through-holes 143 may be formed in a first connection portion 141′.

It has been illustrated and described in the present exemplary embodiment that two first through-holes 143 are formed in the first connection portion 141′, but the number of first through-holes 143 formed in the first connection portion 141′ is not limited thereto, and may be one or three or more.

In addition, the first through-holes 143 may be disposed adjacent to a lower end of the first connection portion 141′. For example, as shown in FIG. 7, the first through-holes 143 may be disposed closer to the lower end of the first connection portion 141′ than to an upper end of the first connection portion 141′. Therefore, when the electronic component is mounted on the circuit board 210, the solder 231 may pass through the first through-holes 143 and then extend to an upper surface of the first mounting portion 142.

In addition, in a second metal frame 150′, second through-holes 153 may be formed in a second connection portion 151′.

It has been illustrated and described in the present exemplary embodiment that two second through-holes 153 are formed in the second connection portion 151′, but the number of second through-holes 153 formed in the second connection portion 151′ is not limited thereto, and may be one or three or more.

In addition, the second through-hole 153 may be disposed adjacent to a lower end of the second connection portion 151′. Similar to the first through-holes 143, the second through-holes 153 may be disposed closer to the lower end of the second connection portion 151′ than to an upper end of the second connection portion 151′. Therefore, when the electronic component is mounted on the circuit board 210, the solder 232 may pass through the second through-hole 153 and then extend to an upper surface of the second mounting portion 152.

A magnitude of thermal stress may be proportional to a length of the connection portion in the Y direction in the metal frame.

In the present exemplary embodiment, a lower end portion of the connection portion at which the solder is positioned may have an unlinear form in the Y direction, and thermal stress occurring on an interface between the mounted surface of the metal frame and the solder may thus be reduced.

In addition, an area in which the solder is in contact with the metal frame may increase by the through-hole, and fixing strength of the mounting portion may thus be further improved.

As set forth above, according to an exemplary embodiment in the present disclosure, durability of the multilayer capacitor against vibrations and deformation may be improved, bonding force between the metal frame and the circuit board may be improved to improve reliability of the electronic component mounted on the circuit board, and a solder crack for attaching the metal frame to the circuit board after the environment test may be prevented to reduce a defective rate of the electronic component.

While exemplary embodiments have been shown and described above, it will be apparent to those skilled in the art that modifications and variations could be made without departing from the scope of the present invention as defined by the appended claims.

What is claimed is:

1. An electronic component comprising:
a capacitor body;
a pair of external electrodes disposed on opposite end surfaces of the capacitor body, respectively; and
a pair of metal frames connected to the pair of external electrodes, respectively,
wherein a coefficient of thermal expansion of the pair of metal frames has a value between a coefficient of thermal expansion of the capacitor body and a coefficient of thermal expansion of a solder.

2. The electronic component of claim 1, wherein the coefficient of thermal expansion of the pair of metal frames is 18.4 ppm/° C. or more.

3. The electronic component of claim 1, wherein the coefficient of thermal expansion of the pair of metal frames is 18.4 to 26.2 ppm/° C.

4. The electronic component of claim 1, wherein the capacitor body includes dielectric layers and a plurality of internal electrodes alternately disposed with each of the dielectric layers interposed therebetween.

5. The electronic component of claim 1, wherein each of the pair of external electrodes includes:
a head portion disposed on one surface among the opposite end surfaces of the capacitor body; and
a band portion extending from the respective head portion onto portions of upper and lower surfaces and opposite side surfaces of the capacitor body that are connected to the opposite end surfaces of the capacitor body.

6. The electronic component of claim 5, wherein each of the pair of metal frames includes:
a connection portion connected to the respective head portion; and
amounting portion bent at and extending from a lower end of the respective connection portion.

7. The electronic component of claim 6, wherein the mounting portion of a first metal frame among the pair of metal frames extends toward the mounting portion of a second metal frame among the pair of metal frames positioned on an opposite side to the mounting portion of the first metal frame.

8. The electronic component of claim 6, wherein each connection portion has at least one through-hole formed therein.

9. Aboard having an electronic component, comprising
a circuit board having a plurality of electrode pads disposed on an upper surface thereof;
an electronic component mounted on the circuit board and including a pair of metal frames connected to the plurality of electrode pads, respectively; and
solders connecting the plurality of electrode pads to the pair of metal frames, respectively,
wherein the electronic component further includes:
a capacitor body; and
a pair of external electrodes disposed on opposite end surfaces of the capacitor body, respectively, and connected to the pair of metal frames, respectively, and
a coefficient of thermal expansion of the pair of metal frames has a value between a coefficient of thermal expansion of the capacitor body and a coefficient of thermal expansion of the solders.

10. The board of claim 9, wherein each of the pair of external electrodes includes:
a head portion disposed on one surface among the opposite end surfaces of the capacitor body; and
a band portion extending from the respective head portion onto portions of upper and lower surfaces and opposite side surfaces of the capacitor body that are connected to the opposite end surfaces of the capacitor body.

11. The board of claim 10, wherein each of the pair of metal frames includes:
a connection portion connected to the respective head portion; and
a mounting portion bent at and extending from a lower end of the respective connection portion.

12. The board of claim 11, wherein each connection portion has at least one through-hole formed therein.

13. The board of claim 12, wherein a portion of each solder passes through the at least one through-hole of the respective connection portion and extends onto an upper surface of the respective mounting portion.

14. The board of claim 12, wherein the at least one through-hole is disposed closer to a lower end of the connection portion, that is connected to the respective mounting portion, than to an upper end of the connection portion.

15. The board of claim 11, wherein the mounting portion of a first metal frame among the pair of metal frames extends toward the mounting portion of a second metal frame among the pair of metal frames positioned on an opposite side to the mounting portion of the first metal frame.

16. The board of claim 9, wherein the coefficient of thermal expansion of the pair of metal frames is 18.4 ppm/° C. or more.

17. The board of claim 9, wherein the coefficient of thermal expansion of the pair of metal frames is 18.4 to 26.2 ppm/° C.

18. The board of claim 9, wherein the capacitor body includes dielectric layers and a plurality of internal electrodes alternately disposed with each of the dielectric layers interposed therebetween.
